(19) United States
(12) Patent Application Publication
(10) Pub. No.: US 2009/0061590 A1
(43) Pub. Date: Mar. 5, 2009

(54) METHOD FOR MANUFACTURING SEMICONDUCTOR DEVICE

(76) Inventor: Sang-Il Hwang, Wonju-si (KR)

Correspondence Address: SHERR & VAUGHN, PLLC, 620 HERNDON PARKWAY, SUITE 200, HERNDON, VA, 20170, US

(21) Appl. No.: 12/201,444

(22) Filed: Aug. 29, 2008

(30) Foreign Application Priority Data
Aug. 31, 2007 (KR) 10-2007-0088248

(51) Int. Cl. H01L 21/768; H01L 21/67

(52) U.S. Cl. 438/401; 29/25.01; 257/E21.585

(57) ABSTRACT

A method for manufacturing a semiconductor device capable of eliminating additional processes for forming an alignment key, thereby shortening the manufacturing process and lowering the manufacturing costs. The method includes forming an insulating layer including wiring regions and an alignment key region over a substrate; forming a first trench and a second trench on the wiring regions and alignment key region of the insulating layer, respectively; laminating a metal layer over the insulating layer including the first trench and second trench, the metal layer completely filling the first trench and partially filling in the second trench and having a height difference between the wiring region and alignment key region; forming a damascene metal wiring in the first trench and forming an alignment mark layer in the second trench by polishing the metal layer; and forming an MIM capacitor over the entire surface of the insulating layer including the metal wiring and alignment mark layer using the alignment mark layer as an alignment key. Since it is not necessary to perform a process for repeatedly forming the alignment key during manufacturing an MIM capacitor, a process for aligning the serial masks is not necessary. Therefore, the manufacturing process can be simplified and the manufacturing cost can be reduced.

The present application claims priority under 35 U.S.C. 119 to Korean Patent Application No. 10-2007-0088248 (filed on Aug. 31, 2007), which is hereby incorporated by reference in its entirety.

### BACKGROUND

Recently, with the appearance of merged memory logic (MML), multimedia functions have been greatly improved. High-integration and high-speed operation of semiconductor devices have been more effectively achieved. To achieve the high-speed operation of logic circuits among the semiconductor devices, a capacitor with high capacitance is in active research and development.

The higher scale integration of semiconductor devices results in a smaller size of a capacitor unit cell and increased capacitance necessary for operating the devices. An analog capacitor applied in a CMOS IC Logic device requiring high precision is a main factor in advanced analog MOS technology, particularly in an A/D converter or a switching capacitor filter field. Structures for an analog capacitor include a Polysilicon/Insulator/Polysilicon (PIP), Polysilicon/Insulator/Metal (PIM), Metal/Insulator/Polysilicon (MIP), and Metal/Insulator/Metal (MIM) structures.

When a capacitor is formed in a Polysilicon/Insulator/Polysilicon (PIP) structure, an oxidation reaction occurs at an interface between upper and lower electrodes and a dielectric thin film, because the upper and lower electrodes are made of conductive polysilicon. Here, natural oxide layer is formed by the oxidation reaction. Thus, there is a disadvantage that the total capacitance is reduced due to the natural oxide layer. Moreover, a depletion region formed in the polysilicon layer reduces the capacitance. Thus, the structure is not suitable for high-speed and high-frequency operations.

To solve the above problems, the structure of the capacitor has been modified into a Metal/Insulator/Polysilicon (MIP) or Metal/Insulator/Metal (MIM) structure. Among these, the MIM capacitor has low specific resistance and no parasitic capacitance caused by the inner depletion. Thus, it is commonly used for high performance semiconductor devices.

However, in a MIM capacitor, both lower and upper electrodes are made of metal layers such that an alignment key in a lower metal wiring layer cannot be seen very well. Therefore, a process to form a height difference or step in the alignment key for aligning a mask must be performed repeatedly.

To form a height difference in the alignment key, a nitride layer must be deposited before depositing the metal layer. Forming the nitride layer requires additional processes such as a photolithography and etching process, which includes depositing, exposing to light, and etching. Thus, manufacturing process times and costs increase.

### SUMMARY

Embodiments relate to a semiconductor device, and more particularly, to a method for manufacturing a semiconductor device capable of eliminating additional processes for forming an alignment key, thereby shortening the manufacturing process and lowering the manufacturing costs. Embodiments relate to a method for manufacturing a semiconductor device capable of eliminating an additional process for forming a height difference or step in an alignment key by providing the height difference in the alignment key region simultaneously with forming a lower metal wiring, thereby simplifying the manufacturing process and lowering the manufacturing cost.

Embodiments relate to a method for manufacturing a semiconductor device which includes:forming an insulating layer including wiring regions and an alignment key region over a substrate; forming a first trench and a second trench on the wiring regions and alignment key region of the insulating layer, respectively; laminating a metal layer over the insulating layer including the first trench and second trench, the metal layer completely filling the first trench and partially filling in the second trench and having a height difference between the wiring region and alignment key region; forming a damascene metal wiring in the first trench and forming an alignment mark layer in the second trench by polishing the metal layer; and forming an MIM capacitor over the entire surface of the insulating layer including the metal wiring and alignment mark layer using the alignment mark layer as an alignment key.

### DRAWINGS

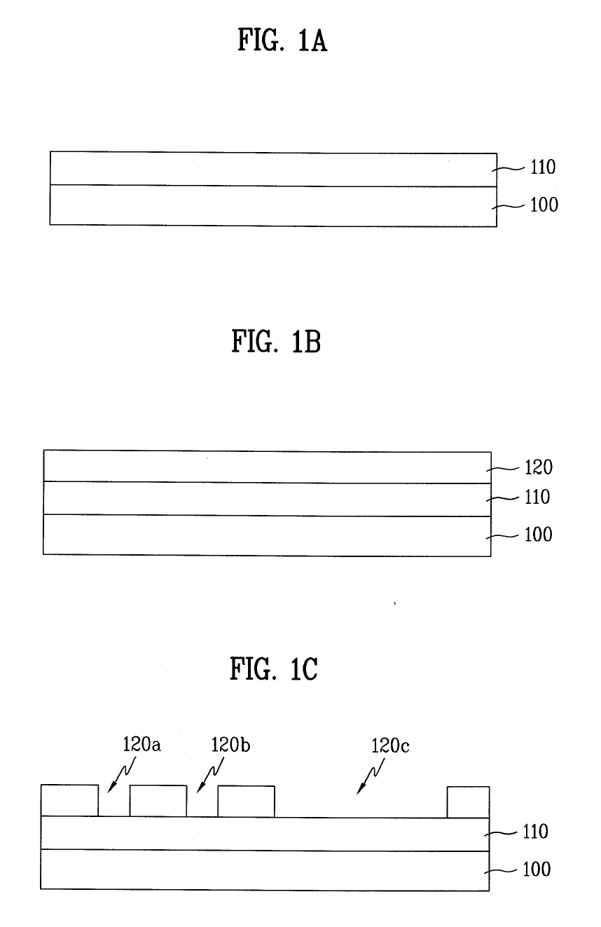

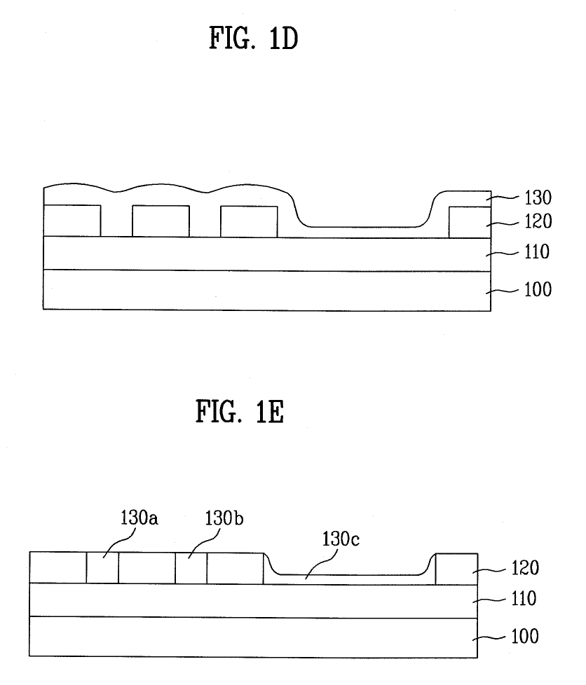

Example FIGS. 1A to 1E are sectional views illustrating a method for manufacturing a semiconductor device according to embodiments.

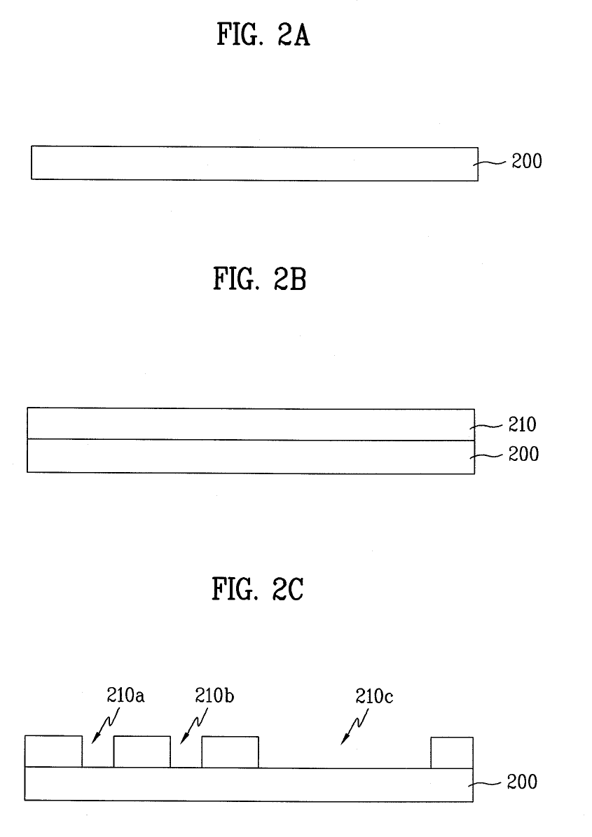

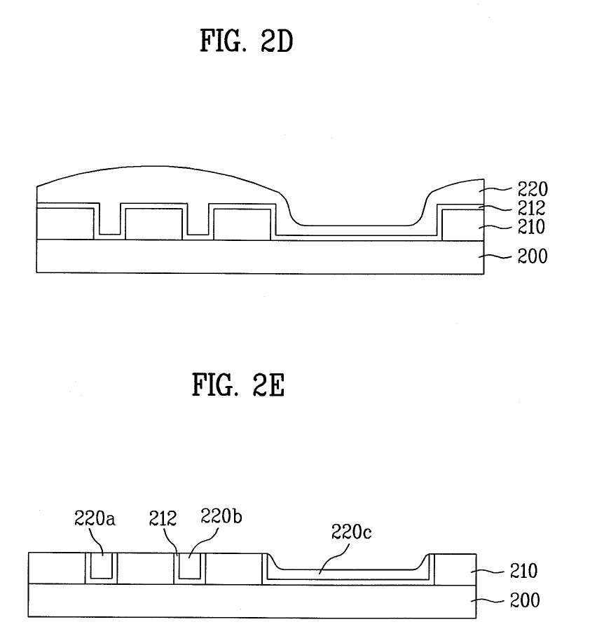

Example FIGS. 2A to 2E are sectional views illustrating a method for manufacturing a semiconductor device according to embodiments.

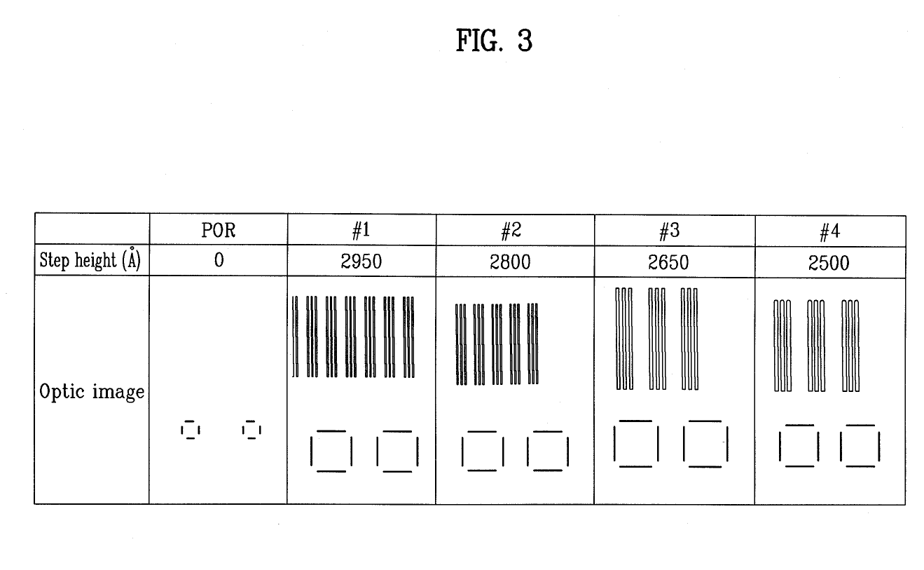

Example FIG. 3 is a series of observations of an alignment key with respect to height differences of 2950 Å, 2800 Å, 2650 Å, and 2500 Å between a damascene metal wiring and an alignment mark layer according to embodiments.

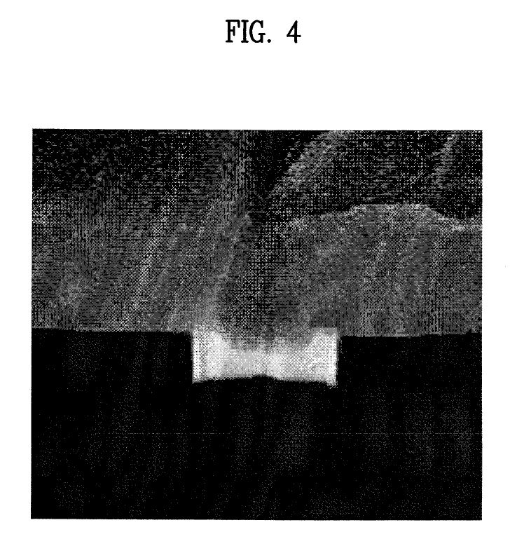

Example FIG. 4 is a sectional view illustrating a height difference of 1400 Å between a height of damascene metal wiring and an alignment mark layer according to embodiments.

### DESCRIPTION

Example FIGS. 1A to 2E are sectional views illustrating a method for manufacturing a semiconductor device according to embodiments. As shown in example FIG. 1A, a lower conductive layer 110 may be formed over a substrate 100. The lower conductive layer 110 may be deposited using a deposition method such as sputtering or plasma enhanced chemical vapor deposition (PECVD). The lower conductive layer 110 may be made of any one metal selected from a group consisting of copper, silver, gold, and nickel, or an alloy of two or more metals selected from the group. Further, the lower conductive layer 110 may be made with the same metal material as the metal to be deposited for an upper metal layer. The lower conductive layer 110 exists only over the substrate including wiring regions and an alignment key region so as to allow partial electrochemical plating in the subsequent process.

Then, as shown in example FIG. 1B, an insulating layer 120 may be formed over the lower conductive layer 110. The insulating layer 120 may be deposited in the same manner as the lower conductive layer 110. The insulating layer 120 may be made of an inorganic or organic insulating material such as silicon oxide SiOₓ or silicon nitride SiNₓ.

Referring to example FIG. 1C, the insulating layer 120 may be patterned by a photolithography and etching process using a mask. As a result, first trenches 120a and 120b may be formed on the wiring regions for forming wirings, and a second trench 120c may be formed on the alignment key region for forming an alignment key. The first trenches 120a and 120b and second trench 120c may be etched so that the top of the lower conductive layer 110 is exposed. The first trenches 120a and 120b and the second trench 120c may have the same height, while the first trenches 120a and 120b may be relatively narrow in width compared to the second trench 120c.

As shown in example FIG. 1D, a metal layer 130 may be formed inside the first trenches 120a and 120b and second trench 120c, which expose the top of the lower conductive layer 110, and over the entire surface of the patterned insulating layer 120 by a damascene process. Here, the metal layer 130 may be formed using the electrochemical plating ECP in the damascene process. Since the lower conductive layer 110 exists under the metal layer 130, the plating can be performed using the partial electrochemical plating method.

The damascene process may be performed using a deposition method such as sputtering or plasma enhanced chemical vapor deposition (PECVD) in addition to the electrochemical plating method.

The metal layer 130 completely fills the first trenches 120a and 120b, and may be laminated over the second trench 120c such that the second trench 120c is partially filled in. The metal layer 130 may be made of any one metal selected from the group consisting of copper, silver, gold, and nickel, or an alloy consisting of at least two metals selected from the group. Further, the metal layer 130 may be made with the same material as the lower conductive layer 110.

Subsequently, as shown in example FIG. 1E, the metal layer 130 may be polished to expose the surface of the insulating layer 120 by chemical mechanical polishing. Metal wirings 130a and 130b may be formed in the first trench regions 120a and 120b, and an alignment mark layer 130c may be formed in the second trench region 120c. The metal wirings 130a and 130b and the alignment mark layer 130c may have a height difference of about 1500 Å to 3500 Å. When the height difference is less than about 1500 Å, the process of forming an alignment key may have to be repeatedly performed during aligning the mask. When the height difference exceeds about 3500 Å, the metal wirings 130a and 130b may not completely fill the first trenches 120a and 120b.

Example FIG. 3 illustrates a series of observations of an alignment key with respect to the thickness of the metal deposited inside the second trench 120c when forming the metal wirings. That is, example FIG. 3 illustrates observations of an alignment key with respect to height differences between the alignment mark layer 130c in the second trench 120c and the metal wirings in the first trench regions 120a and 120b. An alignment key cannot be observed when the height difference between the alignment mark layer and the metal wirings is 0 Å. The alignment key, which may be formed at the same time as the formation of the lower wiring regions, can be observed in the case where the height difference is 2500 Å to 2950 Å.

As shown in example FIGS. 2A and 2B, an insulating layer 210 may be formed over a substrate 200. The insulating layer 210 may be formed in the same manner as the insulating layer 120 of example FIG. 1B. Thereafter, as shown in example FIG. 2C, the insulating layer 210 is patterned by a photolithography and etching process using a mask to form first trenches 210a and 210b for forming metal wirings and a second trench 210c for forming an alignment key. The first trenches may be formed to have narrower widths than the second trench.

As shown in example FIG. 2D, a thin copper seed layer 212 may be formed over the entire surface of the insulating layer 210 including the first trenches 210a and 210b and second trench 210c. The copper seed layer 212 may be deposited using a deposition method such as physical vapor deposition (PVD) or chemical vapor deposition (CVD). Further, a barrier metal layer may be formed between the insulating layer 210 and the copper seed layer 212. The barrier metal layer may be made of tantalum nitride (TaN), Tantalum (Ta), or titanium (Ti). The seed layer 212 is not limited to copper, but also can be made of a metal selected from a group consisting of copper, silver, gold, and nickel, or an alloy including two or more metals selected from the group.

Thereafter, a metal layer 220 may be laminated over the entire surface of the copper seed layer 212 such that the metal layer is completely filled in the first trenches 210a and 210b and partially filled in the second trench 210c. The metal layer 220 may be a metal selected from the group consisting of copper, silver, gold, and nickel, or an alloy of two or more metals selected from the group.

Subsequently, as shown in example FIG. 2E, the metal layer 220 may be polished to expose the surface of the insulating layer 210 by chemical mechanical polishing. Metal wirings 220a and 220b may be formed on the first trench regions 210a and 210b and an alignment mark layer 220c may be formed in the second trench region 210c. The height difference between the metal wirings 220a and 220b and the alignment mark layer 220c may be about 1500 Å to 3500 Å. When the height difference is less than about 1500 Å, the process of forming an alignment key may have to be repeatedly performed during aligning the mask. When the height difference exceeds about 3500 Å, the metal wirings 220a and 220b may not completely fill the first trenches 210a and 210b.

In the same manner as above, the alignment key is partially filled in the second trench region 210c using electrochemical plating when forming the metal wirings in the first trench regions 210a and 210b. As a result, a height difference between the insulating layer and the alignment mark layer can be maintained even after the chemical mechanical polishing of the metal layer. Therefore, the position of the alignment key can be observed during the subsequent processes for forming an MIM capacitor even when the metal layer is opaque.

Example FIG. 4 is a sectional view of an alignment key region when a height difference between metal wirings and an alignment mark layer is generated. Referring to example FIG. 4, the height difference between the metal wirings and the alignment mark layer is about 1400 Å. Thus, the height difference in the alignment key region occurs even after the metal layer is formed thereon using electrochemical plating.

Since it is not necessary to perform a process for repeatedly forming the alignment key during manufacturing an MIM capacitor, a process for aligning the serial masks is not necessary. Therefore, the manufacturing process can be simplified and the manufacturing cost can be reduced.

In the method for manufacturing a semiconductor device according to embodiments, a height difference in the alignment key may be achieved using an electroplating method when forming a copper layer for the lower wiring. Thus, since no additional deposition process is required to achieve the height difference in the alignment key, the manufacturing process can be simplified and the manufacturing cost can be lowered.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an insulating layer including wiring regions and an alignment key region over a substrate;
forming a first trench on the wiring regions of the insulating layer;
forming a second trench on the alignment key region of the insulating layer;
laminating a metal layer over the insulating layer including the first trench and second trench, the metal layer completely filling the first trench and partially filling the second trench and having a height difference between the wiring region and the alignment key region;
forming a damascene metal wiring in the first trench and forming an alignment mark layer in the second trench by polishing the metal layer; and
forming a metal-insulator-metal capacitor over the entire surface of the insulating layer including the metal wiring and alignment mark layer using the alignment mark layer as an alignment key.

2. The method of claim 1, comprising forming a lower conductive layer which includes the wiring regions and the alignment key region before forming the insulating layer.

3. The method of claim 2, wherein the lower conductive layer comprises at least one of copper, silver, gold, and nickel.

4. The method of claim 2, wherein the lower conductive layer comprises a metal alloy of at least two of copper, silver, gold, and nickel.

5. The method of claim 2, wherein the lower conductive layer is made with substantially the same material used for the metal layer.

6. The method of claim 1, wherein the first trench has a narrower width than the second trench.

7. The method of claim 1, wherein in said laminating the metal layer, the metal layer is formed inside the first and second trenches and over the entire surface of the insulating layer using electrochemical plating.

8. The method of claim 7, comprising forming a metal seed layer inside the first and second trenches and over the entire surface of the insulating layer before forming the metal layer.

9. The method of claim 7, wherein the metal layer comprises at least one of copper, silver, gold, and nickel.

10. The method of claim 7, wherein the metal layer comprises a metal alloy of at least two of copper, silver, gold, and nickel.

11. The method of claim 8, comprising forming a barrier metal layer inside the first and second trenches and over the entire surface of the insulating layer before forming the seed metal layer.

12. The method of claim 11, wherein the barrier metal layer comprises at least one of tantalum nitride, tantalum, and titanium.

13. The method of claim 1, wherein the damascene metal wirings and the alignment mark layer have a height difference of about 1500 Å to 3500 Å.

14. A method comprising:
forming a lower conductive layer over a substrate which includes wiring regions and an alignment key region.
forming an insulating layer including over the wiring regions and the alignment key region;
forming a first trench on the wiring regions of the insulating layer;
forming a second trench on the alignment key region of the insulating layer, wherein the second trench is wider than the first trench;
forming a barrier metal layer inside the first and second trenches and over the entire surface of the insulating layer;
forming a metal seed layer inside the first and second trenches and over the entire surface of the insulating layer;
laminating a metal layer using electrochemical plating over the insulating layer including the first trench and second trench, the metal layer being made from the same material as the lower conductive layer, the metal layer completely filling the first trench and partially filling the second trench and having a height difference between the wiring region and the alignment key region;
forming a damascene metal wiring in the first trench and forming an alignment mark layer in the second trench by polishing the metal layer, wherein the damascene metal wirings and the alignment mark layer have a height difference of about 1500 to 3500 Å; and
forming an a metal-insulator-metal capacitor over the entire surface of the insulating layer including the metal wiring and alignment mark layer using the alignment mark layer as an alignment key.

15. The method of claim 14, wherein the barrier metal layer comprises at least one of tantalum nitride, tantalum, and titanium.

16. The method of claim 14, wherein the lower conductive layer comprises at least one of copper, silver, gold, and nickel.

17. An apparatus configured to:
form an insulating layer including wiring regions and an alignment key region over a substrate;
form a first trench on the wiring regions of the insulating layer;
form a second trench on the alignment key region of the insulating layer;
laminate a metal layer over the insulating layer including the first trench and second trench, the metal layer completely filling the first trench and partially filling the second trench and having a height difference between the wiring region and the alignment key region;
form a damascene metal wiring in the first trench and forming an alignment mark layer in the second trench by polishing the metal layer; and
form an a metal-insulator-metal capacitor over the entire surface of the insulating layer including the metal wiring and alignment mark layer using the alignment mark layer as an alignment key.

18. The apparatus of claim 17, configured to form a lower conductive layer which includes the wiring regions and the alignment key region before forming the insulating layer.

19. The apparatus of claim 17, configured to form the first trench with a narrower width than the second trench.

20. The apparatus of claim 17, configured to form the damascene metal wirings and the alignment mark layer to have a height difference of about 1500 to 3500 Å.
